(19) United States
(12) Patent Application Publication
(10) Pub. No.: US 2025/0080099 A1
(43) Pub. Date: Mar. 6, 2025

(54) ELECTROSTATIC DISCHARGE PROTECTION CIRCUIT

(71) Applicant: STMicroelectronics International N.V., Geneva (CH)

(72) Inventors: Philippe GALY, Le Touvet (FR); Serge PONTAROLLO, Saint-Egreve (FR)

(73) Assignee: STMicroelectronics International N.V., Geneva (CH)

(21) Appl. No.: 18/809,905

(22) Filed: Aug. 20, 2024

(30) Foreign Application Priority Data
Aug. 28, 2023 (FR) 2308975

(51) Int. Cl. H03K 17/081

(52) U.S. Cl. CPC H03K 17/08104

(57) ABSTRACT

An electrostatic discharge protection circuit protects a first transistor. The circuit includes N diodes in series between conduction terminals of the first transistor. A second transistor and third transistor are connected in series between the conduction terminals of the first transistor. A control terminal of the third transistor is coupled to an anode of the N diodes. A first inverter couples the control terminals of the first and second transistors. A fourth transistor is connected in parallel with the first transistor. A control terminal of the fourth transistor is coupled to the junction point of the second and third transistors. A capacitor is arranged between the control terminal of the fourth transistor and a conduction terminal of the first transistor.

### PRIORITY CLAIM

This application claims the priority benefit of French Application for U.S. Pat. No. 2,308,975, filed on Aug. 28, 2023, the content of which is hereby incorporated by reference in its entirety to the maximum extent allowable by law.

### TECHNICAL FIELD

The present disclosure generally concerns electronic circuits and devices and further concerns protection against electrostatic discharges. The present description more particularly concerns an electrostatic discharge protection circuit.

### BACKGROUND

The protection of electronic circuits against electrostatic discharges is a significant issue to ensure the reliability and the durability of electronic circuits, and in particular of integrated circuits.

An electrostatic discharge protection device is a device which is arranged between two nodes of a circuit to be protected against electrostatic discharges. On the physical circuit, these two nodes are generally materialized by connection pads. These two nodes may be, for example, the input and output nodes of an electronic device, or power supply nodes of an electronic device.

It would be desirable to be able to improve, at least partly, certain aspects of known electrostatic discharge protection devices.

There exists a need for higher-performance protection circuits.

There is a need to overcome all or part of the disadvantages of known electrostatic discharge protection circuits.

### SUMMARY

An embodiment provides a circuit of protection against electrostatic discharges of a first transistor of a first type comprising: N diodes in series between a first conduction terminal of said first transistor and a second conduction terminal of said first transistor, N being an integer, the turn-on voltage of the N diodes being higher, whatever the temperature, than a power supply voltage; a second transistor of the first type in series with a third transistor of a second type different from the first type between the first conduction terminal of said first transistor and the second conduction terminal of said first transistor, wherein a control terminal of said third transistor is coupled to an anode of said N diodes; a first inverter coupling a control terminal of said first transistor to a control terminal of said second transistor; a fourth transistor in parallel with said first transistor, a control terminal of said fourth transistor being coupled to a junction point of said second transistor and third transistor; and a first capacitor arranged between the control terminal of said fourth transistor and the first conduction terminal of said first transistor.

According to an embodiment, the circuit further comprises a first resistor coupling said anode of said N diodes and the first conduction terminal of said first transistor.

According to an embodiment, N is between ten and twenty.

According to an embodiment, N is equal to fourteen.

According to an embodiment, the circuit further comprises a second resistor coupling said control terminal of said fourth transistor to said second conduction terminal of said first transistor.

According to an embodiment, the circuit further comprises a fifth transistor coupling said second resistor to said second conduction terminal of said first transistor.

According to an embodiment, the circuit further comprises a second capacitor arranged in series with the first capacitor.

According to an embodiment, the circuit further comprises a first diode arranged between a junction node of said first capacitor and second capacitor, and said second conduction terminal of said first transistor.

According to an embodiment, the circuit further comprises a second diode arranged in parallel with said second resistor.

According to an embodiment, said first conduction terminal of said first transistor is configured to receive a reference voltage.

According to an embodiment, the reference voltage is the ground.

According to an embodiment, said first, second, third, fourth transistors are transistors of same technology.

According to an embodiment, the fifth transistor is of same technology as said first, second, third, fourth transistors.

According to an embodiment, said first, second, third, fourth transistors are drift MOS transistors.

Another embodiment provides an electronic device comprising said first transistor and an electrostatic discharge protection circuit described hereabove.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 schematically and partially shows in the form of blocks a portion of an electronic device;

FIG. 2 shows an electric diagram of a first embodiment of an electrostatic discharge protection circuit;

FIG. 3 shows an electric diagram of a second embodiment of an electrostatic discharge protection circuit;

FIG. 4 shows an electric diagram of a third embodiment of an electrostatic discharge protection circuit;

FIG. 5 shows an electric diagram of a fourth embodiment of an electrostatic discharge protection circuit; and

FIG. 6 shows an electric diagram of a fifth embodiment of an electrostatic discharge protection circuit.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for the understanding of the described embodiments have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “front”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred, unless specified otherwise, to the orientation of the drawings.

Unless specified otherwise, the expressions “about”, “approximately”, “substantially”, and “in the order of” signify plus or minus 10%, preferably of plus or minus 5%.

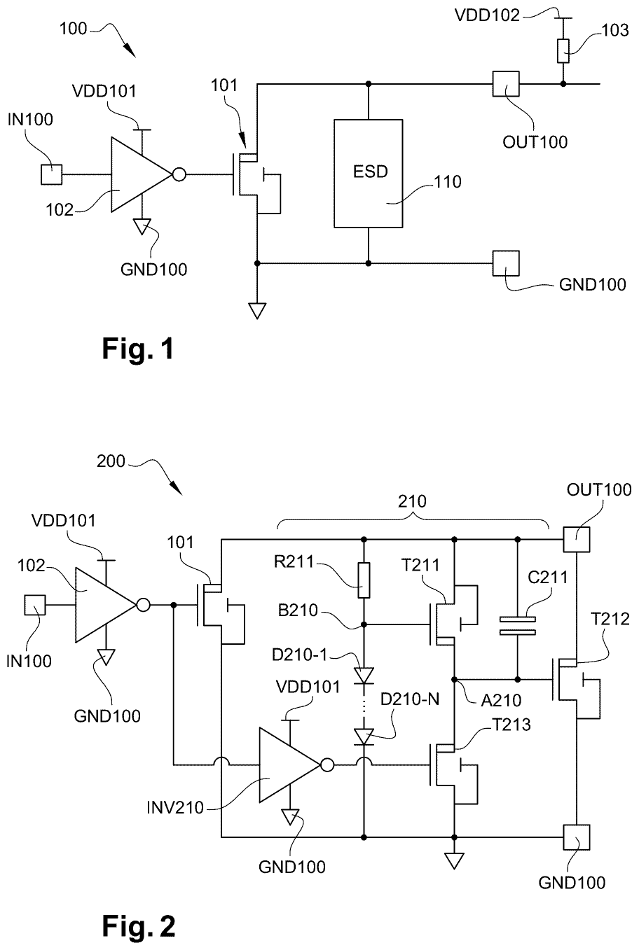

FIG. 1 schematically and partially shows in the form of blocks a portion of an electronic device equipped 100 with an embodiment of an electrostatic discharge protection circuit 110.

Electronic device 100 comprises a transistor 101 to be protected. Transistor 101 may be of different technologies described hereafter. Transistor 101 comprises a first conduction terminal coupled, preferably connected, to an output node OUT100 of device 100, and a second conduction terminal coupled, preferably connected, to a reference node GND100 configured to receive a reference voltage, for example the ground. Transistor 101 further comprises a control terminal. Transistor 101 is further characterized by its breakdown voltage between its conduction terminals BVDSS101, that is, the limiting voltage that transistor 101 accepts between its conduction terminals.

According to a first example, transistor 101 may be a metal-oxide semiconductor field-effect transistor (MOSFET) or MOS transistor. Further, transistor 101 is an N-channel MOS transistor, or N-type MOS transistor, or NMOS transistor. In this case, the drain terminal of transistor 101 is coupled, preferably connected, to node OUT100, and the source terminal of transistor 101 is coupled, preferably connected, to reference node GND100.

According to a second example, transistor 101 may be a drift metal-oxide semiconductor field-effect transistor, or a drain extension metal-oxide semiconductor field-effect transistor, or drift MOSFET transistor, or drain extension MOSFET transistor, or drift MOS transistor. Further, transistor 101 is an N-channel drift MOS transistor, or N-type drift MOS transistor, or drift NMOS transistor. A drift NMOS transistor is an NMOS transistor having its N-type doped drain region which is not in direct contact with the channel-forming region, but is in contact via a drain drift region, or extended drain region, more lightly N-type doped, with the channel-forming region. A drift NMOS transistor has a greater breakdown voltage between its conduction terminals than a conventional NMOS transistor of similar dimensions. According to a specific example, transistor 101 has a voltage BVDSS in the order of 20 V, for example equal to 17 V. In this case, the drain terminal of transistor 101 is coupled, preferably connected, to node OUT100, and the source terminal of transistor 101 is coupled, preferably connected, to reference node GND100. In FIG. 1, transistor 101 is represented by the electric symbol of a drift NMOS transistor.

It should be noted that there also exist P-channel drift MOS transistors, or P-type drift MOS transistors, or PMOS drift transistors. A PMOS drift transistor is a PMOS transistor having a P-type doped drain region which is not in direct contact with the channel-forming region, but is in contact via a drain drift region, or extended drain region, deeply P-type doped, with the channel-forming region.

According to a third example, transistor 101 is an NPN-type bipolar transistor. In this case, the collector terminal of transistor 101 is coupled, preferably connected, to node OUT100, and the emitter terminal of transistor 101 is coupled, preferably connected, to reference node GND100.

According to an example, electronic device 100 further comprises an inverter circuit 102. An input terminal of inverter circuit 102 is coupled, preferably connected, to an input node IN100 of device 100, and an output terminal of circuit 102 is coupled, preferably connected, to the control terminal of transistor 101. Inverter circuit 102 is configured to be powered with a power supply voltage VDD101, and to be coupled to reference node GND100. According to a preferred example, power supply voltage VDD101 is the general power supply voltage of device 100.

According to an example, electronic device 100 further comprises a pull-up resistor 103 having a conduction terminal coupled, preferably connected, to output node OUT100. A second conduction terminal of resistor 103 is configured to be powered with a power supply voltage VDD102 which may be different from power supply voltage VDD101. According to an example, power supply voltage VDD102 may be greater than power supply voltage VDD101. According to an example, power supply voltage VDD102 is an auxiliary power supply voltage of device 100.

As previously mentioned, and according to an embodiment, electronic device 100 further comprises an electrostatic discharge protection circuit 110. Circuit 110 is assembled so as to absorb an electrostatic discharge occurring between nodes OUT100 and GND100. More particularly, circuit 100 is configured to protect transistor 101 whatever the manufacturing, voltage, and temperature variations, and in particular whatever the temperature conditions. Several embodiments of circuit 110 are described in detail in relation with FIGS. 2 to 6.

FIG. 2 schematically and partially shows in the form of blocks a portion of an electronic device 200 equipped with an embodiment of an electrostatic discharge protection circuit 210 of the type of the circuit 110 described in relation with FIG. 1.

The portion of device 200 described in relation with FIG. 2 is similar to the portion of device 100 described in relation with FIG. 1. The elements common to devices 100 and 200 are not described in detail again herein, and only the differences between devices 100 and 200 are highlighted.

Thus, device 200 comprises transistor 101, inverter 102, resistor 103 (not shown in FIG. 2), and nodes IN100, OUT100, and GND100. Device 200 differs from device 100 in that it comprises an electrostatic discharge protection circuit 210 instead of circuit 110.

Circuit 210 comprises two transistors T211 and T212 of same technology as transistor 101. According to the example shown in FIG. 2, transistors T211 and T212 are drift MOS transistors like transistor 101. Further, transistor T212 is of the same type as transistor 101, that is, of type N, and transistor T211 is of the type opposite to transistor 101, that is, of type P. Transistor T211 comprises a source terminal coupled, preferably connected, to output node OUT100, and a drain terminal coupled, preferably connected, to a node A210. Transistor T211 comprises a gate terminal coupled, preferably connected, to a node B210. Transistor T212 comprises a source terminal coupled, preferably connected, to reference node GND100, and a drain terminal coupled, preferably connected, to output node OUT100. Transistor T212 comprises a gate terminal coupled, preferably connected, to node A210.

According to an embodiment, transistor T211 is a transistor for starting circuit 210, and transistor T212 is a power transistor configured to direct an electrostatic discharge towards reference node GND100. For this purpose, transistors T211 and T212 have, respectively, breakdown voltages between their conduction terminals BVDSS211 and BVDSS212 each equal to the breakdown voltage BVDSS211 of transistor 101.

Circuit 210 further comprises a resistor R211 arranged between output node OUT100 and node B210. The resistor is sized to configure the value of the voltage of an electrostatic discharge to the voltage level acceptable by the gate of transistor T211. In other words, the resistance value is configured to turn on transistor T211 only on occurrence of an electrostatic discharge.

Circuit 210 further comprises N diodes D210-1 to D210-N, N being an integer, arranged in series between node B210 and reference node GND100. It is here said that two diodes are arranged in series if the anode of a first diode is coupled to the cathode of a second diode. In the case of circuit 210, the anode of diode D210-1 is coupled, preferably connected, to node B210, and the cathode of diode D210-N is coupled, preferably connected, to reference node GND100. According to an embodiment, integer N is between 10 and 30, for example between 10 and 20, preferably equal to 14. In practice, diodes D210-1 to D210-N may be diode-assembled transistors.

Diodes D210-1 to D210-N are used, with resistor R211, as a static mode for starting circuit 210. According to an embodiment, the sum of the threshold voltages, called turn-on voltage, of diodes D210-1 to D210-N is smaller than the avalanche voltages of transistors T211 and T212, and is greater than power supply voltage VDD100.

Circuit 210 further comprises a capacitor C211, a transistor T213, and an inverter circuit INV211. A first conduction terminal of capacitor C211 is coupled, preferably connected, to output node OUT100, and a second conduction terminal of capacitor C211 is coupled, preferably connected, to node A210. Transistor T213 is of the same technology and of the same type as transistor 101. In other words, in FIG. 2, transistor T213 is a drift NMOS transistor. The drain terminal of transistor T213 is coupled, preferably connected, to node A210, and the source terminal of transistor T213 is coupled, preferably connected, to reference node GND100. An input terminal of inverter circuit INV211 is coupled, preferably connected, to the output terminal of inverter circuit 102, and an output terminal of circuit INV211 is coupled, preferably connected, to the control terminal of transistor T213. Inverter circuit INV211 is configured to receive power supply voltage VDD101, and to be coupled to reference node GND100.

In other words, transistor T213 is coupled in series with transistor T211 between nodes OUT100 and GND100. It is here said that two transistors are coupled in series between two nodes if a first conduction terminal of a transistor is coupled, preferably connected, to a first conduction terminal of the other transistor.

Capacitor C211 is used to improve the rapidity of the starting of transistor T212 at the time of the occurrence of an electrostatic discharge, and enables to implement a capacitive coupling at the control terminal of transistor T212.

Transistor T213 and inverter INV211 enable to prevent the starting of transistor T212 when transistor 101 is intentionally started, that is, on occurrence of a rising edge on the voltage between nodes OUT100 and GND100, that is, on the output voltage of transistor 101, which is not an electrostatic discharge.

An advantage of circuit 210 is that it enables to provide an electrostatic discharge protection with a rapid execution, and a protection adapted to voltages ranging up to 17 V.

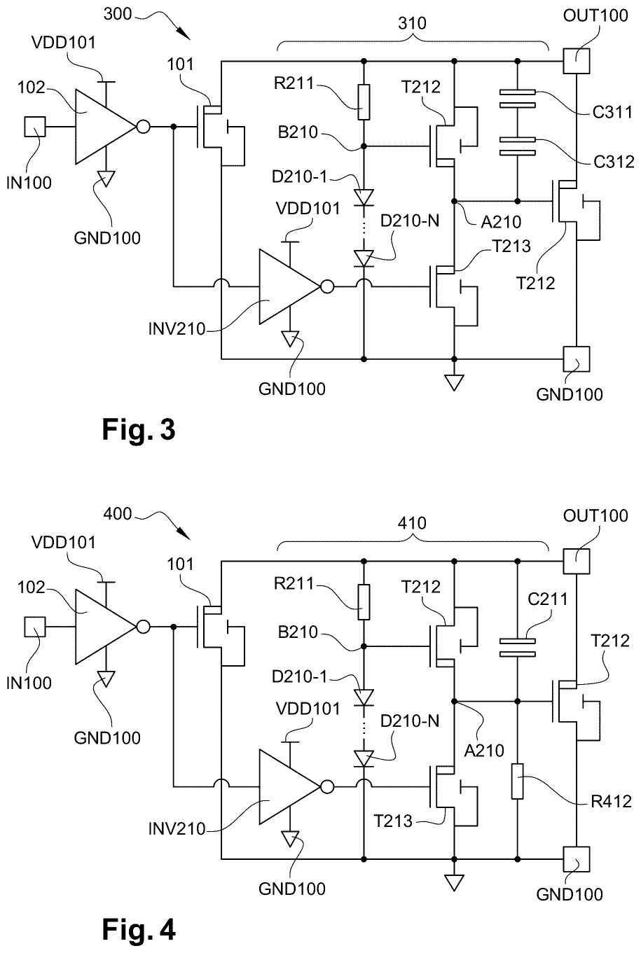

FIG. 3 schematically and partially shows in the form of blocks a portion of an electronic device 300 equipped with an embodiment of an electrostatic discharge protection circuit 310 of the type of the circuit 110 described in relation with FIG. 1.

The portion of device 300 described in relation with FIG. 3 is similar to the portions of devices 100 and 200 described in relation with FIGS. 1 and 2. Thus, device 300 comprises transistor 101, inverter 102, resistor 103 (not shown in FIG. 3), and nodes IN100, OUT100, and GND100. The difference between devices 100 and 200 and device 300 is that device 300 comprises an electrostatic discharge protection circuit 310 instead of circuits 110 and 210.

Circuit 310 is similar to the circuit 210 described in relation with FIG. 2. The elements commons to circuits 210 and 310 are not described in detail again herein. Only the differences between circuits 210 and 310 are highlighted.

Thus, circuit 310 comprises: transistors T211 and T212; diodes D210-1 to D210-N; resistor R211; transistor T213; and inverter circuit INV201.

The difference between circuit 310 and circuit 210 is that the capacitor C211 of circuit 210 is replaced with two capacitors C311 and C312 arranged in series between nodes OUT100 and A210. According to an example, capacitors C311 and C312 each have a capacitance in the order of 16 pF, which is equivalent to an equivalent capacitance for the two capacitors C311 and C312 in the order of 8 pF.

An advantage of this embodiment is that it enables to improve the supporting of high voltages. Indeed, the use of a single capacitive element may result being insufficient with respect to the management of the high voltage on node OUT100.

FIG. 4 schematically and partially shows in the form of blocks a portion of an electronic device 400 equipped with an embodiment of an electrostatic discharge protection circuit 410 of the type of the circuit 110 described in relation with FIG. 1.

The portion of device 400 described in relation with FIG. 4 is similar to the portions of devices 100, 200, and 300 described in relation with FIGS. 1 to 3. Thus, device 400 comprises transistor 101, inverter 102, resistor 103 (not shown in FIG. 4), and nodes IN100, OUT100, and GND100. The difference between devices 100, 200, 300 and device 400 is that device 500 comprises an electrostatic discharge protection circuit 410 instead of circuits 110, 210, 310.

Circuit 410 is similar to the circuit 210 described in relation with FIG. 2. The elements commons to circuits 210 and 410 are not described in detail again herein. Only the differences between circuits 210 and 410 are highlighted.

Thus, circuit 410 comprises: transistors T211 and T212; diodes D210-1 to D210-N; resistor R211; capacitor C211; transistor T213; and inverter circuit INV201.

The difference between circuit 410 and circuit 210 is that circuit 410 further comprises a resistor R412. According to an embodiment, a first conduction terminal of resistor R412 is coupled, preferably connected, to node A210, and a second conduction terminal of resistor R412 is coupled, preferably connected, to reference node GND100. According to an example, resistor R412 has a resistivity between 1 and 100 kOhms, for example in the order of 49 kOhms.

An advantage of this embodiment is that the adding of resistor R412 forms a start circuit of RC (Resistor-Capacitor) type with the capacitor C211 of transistor T212.

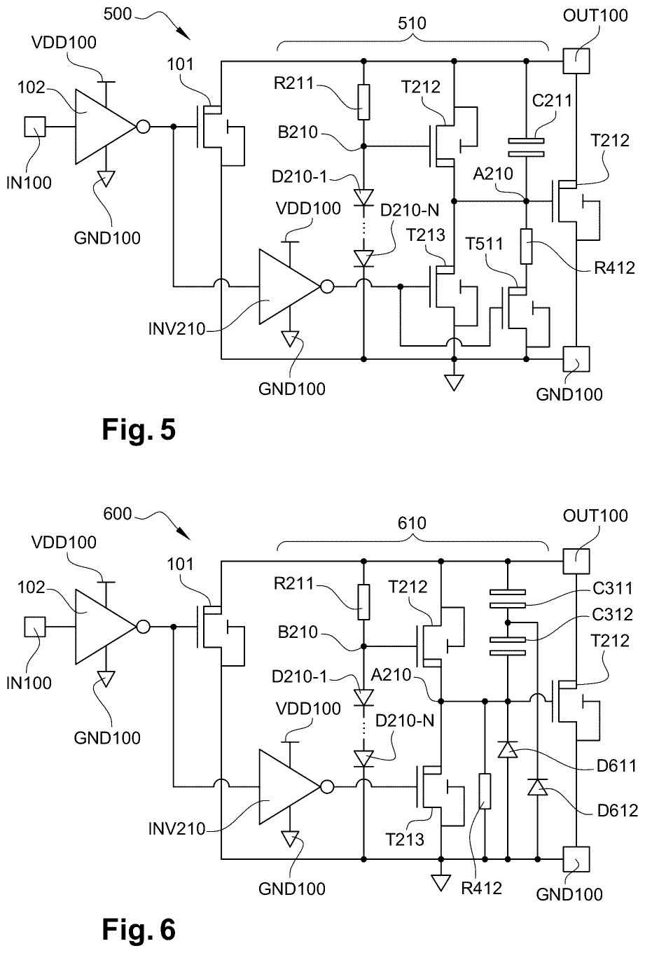

FIG. 5 schematically and partially shows in the form of blocks a portion of an electronic device 500 equipped with an embodiment of an electrostatic discharge protection circuit 510 of the type of the circuit 110 described in relation with FIG. 1.

The portion of device 500 described in relation with FIG. 5 is similar to the portions of devices 100, 200, 300, and 400 described in relation with FIGS. 1 to 4. Thus, device 500 comprises transistor 101, inverter 102, resistor 103 (not shown in FIG. 5), and nodes IN100, OUT100, and GND100. The difference between devices 100, 200, 300, 400 and device 500 is that device 500 comprises an electrostatic discharge protection circuit 510 instead of circuits 110, 210, 310, and 410.

Circuit 510 is similar to the circuit 410 described in relation with FIG. 4. The elements common to circuits 510 and 410 are not described in detail again herein. Only the differences between circuits 410 and 510 are highlighted.

Thus, circuit 510 comprises: transistors T211 and T212; diodes D210-1 to D210-N; resistor R211; capacitor C211; resistor R412; transistor T213; and inverter circuit INV201.

The difference between circuit 510 and circuit 410 is that circuit 510 further comprises a transistor T511 enabling to activate or to deactivate the effect of resistor R412. Transistor T511 is of the same technology and of the same type as transistor 101. In FIG. 5, transistor T511 thus is a drift NMOS transistor.

Transistor T511 is coupled in series with resistor R412 between nodes A210 and GND100. For this purpose, a drain terminal of transistor T511 is coupled, preferably connected, to the second conduction terminal of resistor R12, and a source terminal of transistor T511 is coupled, preferably connected, to reference node GND100. The control terminal of transistor T511, that is, the gate terminal of transistor T511, is coupled, preferably connected, to the output of inverter circuit 102.

An advantage of this embodiment is that transistor T511 enables not to activate resistor R412 on occurrence of a desired rising edge at the output of the transistor 101 to be protected. In other words, transistor T511 enables to avoid implementing circuit 510 when transistor 101 exhibits a desired rising edge at its output.

FIG. 6 schematically and partially shows in the form of blocks a portion of an electronic device 600 equipped with an embodiment of an electrostatic discharge protection circuit 610 of the type of the circuit 110 described in relation with FIG. 1.

The portion of device 600 described in relation with FIG. 6 is similar to the portions of devices 100, 200, 300, 400, and 500 described in relation with FIGS. 1 to 5. Thus, device 600 comprises transistor 101, inverter 102, resistor 103 (not shown in FIG. 6), and nodes IN100, OUT100, and GND100. The difference between devices 100, 200, 300, 400, 500, and device 600 is that device 600 comprises an electrostatic discharge protection circuit 610 instead of circuits 110, 210, 310, 410, and 510.

Circuit 610 is similar to the circuit 310 described in relation with FIG. 3 and to the circuit 410 described in relation with FIG. 4. The elements common to circuits 310, 410, and 610 are not described in detail again herein. Only the differences between circuits 310, 410, and 610 are highlighted.

More particularly, circuit 610 is a combination of circuits 310 and 410. Thus, circuit 510 comprises: transistors T211 and T212; diodes D210-1 to D210-N; resistor R211; capacitors C311 and C312; resistor R412; transistor T213; and inverter circuit INV201.

According to an embodiment, circuit 610 might further comprise the transistor T511 described in relation with FIG. 5.

Circuit 610 further comprises two diodes D611 and D612. A cathode terminal of diode D611 is coupled, preferably connected, to node A210, and an anode terminal of diode D611 is coupled, preferably connected, to reference node GND100. A cathode terminal of diode D612 is coupled, preferably connected, to the junction node of capacitors C311 and C312, and an anode terminal of diode D612 is coupled, preferably connected, to reference node GND100.

An advantage of this embodiment is that diodes D611 and D612 enable to decrease, and sometimes to avoid, the occurrence of an antenna effect on manufacturing of circuit 610. An antenna effect is an effect of charge build up in the gate of power transistor T212 during the carrying out of certain etch operations, in particular plasma etchings.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. An electrostatic discharge protection circuit for a first transistor of a first type, comprising:
N diodes in series between a first conduction terminal of said first transistor and a second conduction terminal of said first transistor, N being an integer, wherein a turn-on voltage of the N diodes is greater, whatever the temperature, than a power supply voltage;
a second transistor of the first type in series with a third transistor of a second type different from the first type, wherein the second and third transistors are connected between the first conduction terminal of said first transistor and the second conduction terminal of said first transistor, wherein a control terminal of said third transistor is coupled to an anode of said N diodes;
a first inverter coupling a control terminal of said first transistor to a control terminal of said second transistor;
a fourth transistor in parallel with said first transistor, wherein a control terminal of said fourth transistor is coupled to a junction point of said second transistor and third transistor; and
a first capacitor arranged between the control terminal of said fourth transistor and the first conduction terminal of said first transistor.

2. The circuit according to claim 1, further comprising a first resistor coupling said anode of said N diodes and the first conduction terminal of said first transistor.

3. The circuit according to claim 1, wherein N is between ten and twenty.

4. The circuit according to claim 3, wherein N is equal to fourteen.

5. The circuit according to claim 1, further comprising a second resistor coupling said control terminal of said fourth transistor to said second conduction terminal of said first transistor.

6. The circuit according to claim 5, further comprising a fifth transistor coupled in series with said second resistor between said second conduction terminal of said first transistor and said control terminal of said fourth transistor.

7. The circuit according to claim 1, further comprising a second capacitor arranged in series with the first capacitor between said control terminal of said fourth transistor and said first conduction terminal of said first transistor.

8. The circuit according to claim 1, further comprising a first diode arranged between a junction node of said first capacitor and second capacitor and said second conduction terminal of said first transistor.

9. The circuit according to claim 1, further comprising a second diode arranged in parallel with said second resistor.

10. The circuit according to claim 1, wherein said second conduction terminal of said first transistor is configured to receive a reference voltage.

11. The circuit according to claim 10, wherein the reference voltage is the ground.

12. The circuit according to claim 10, wherein the first conduction terminal of said first transistor is configured as an output node.

13. The circuit according to claim 1, wherein said first, second, third, fourth transistors are transistors of same technology.

14. The circuit according to claim 13, further comprising a fifth transistor coupling said second resistor to said second conduction terminal of said first transistor, and wherein the fifth transistor is of same technology as said first, second, third, fourth transistors.

15. The circuit according to claim 13, wherein said first, second, third, fourth transistors are drift MOS transistors.

16. An electronic device, comprising:
said first transistor; and
the electrostatic discharge protection circuit according to claim 1.
